(19) United States
(12) Patent Application Publication
(10) Pub. No.: US 2018/0183002 A1
(43) Pub. Date: Jun. 28, 2018

(54) DISPLAY DEVICE

(71) Applicant: Japan Display Inc., Tokyo (JP)

(72) Inventor: Yasushi KAWATA, Tokyo (JP)

(73) Assignee: Japan Display Inc., Tokyo (JP)

(21) Appl. No.: 15/818,847

(22) Filed: Nov. 21, 2017

(30) Foreign Application Priority Data
Dec. 26, 2016 (JP) 2016-251358

(51) Int. Cl. H01L 51/52; H01L 51/00; H01L 27/32; H01L 51/56; B32B 7/12

(52) U.S. Cl. CPC H01L 51/5246; H01L 51/0097; H01L 51/5253; H01L 27/3211; H01L 51/56; B32B 2307/206; H01L 2251/5338; H01L 27/3244; H01L 2227/323; B32B 2457/20; B32B 7/12

(57) ABSTRACT

According to one embodiment, a display device includes an an insulating substrate, and a supporting substrate, a protective member. The insulating substrate includes a first upper surface and a first lower surface. The supporting substrate includes a second upper surface and a second lower surface. The second upper surface is attached to the first lower surface. The protective member is attached to the first upper surface. The second upper surface is smaller than the first upper surface. The first upper surface is smaller than the protective member.

### CROSS-REFERENCE TO RELATED APPLICATIONS

This application is based upon and claims the benefit of priority from Japanese Patent Application No. 2016-251358, filed Dec. 26, 2016, the entire contents of which are incorporated herein by reference.

### FIELD

Embodiments described herein relate generally to a display device.

### BACKGROUND

A display device comprises a display panel, and a glass cover which protects the display panel. The display panel comprises a sheet-like substrate on which optical elements such as an organic electroluminescent (EL) element and a liquid crystal layer are formed.

In a process for manufacturing a display device, to improve the productivity, a technology of simultaneously forming a plurality of cell substrates on a substrate and cutting the substrate into individual cells with laser light or rotary teeth is known. An end face of a cell substrate makes an obtuse angle with the first upper surface of the cell substrate on the display side, and makes an acute angle with the second lower surface on the rear side.

When a grass cover is attached to the above substrate, a wedge-shaped gap is defined between the rear surface of the glass cover and an end face of the substrate. Thus, air bubbles easily intrude based on the gap. Further, the area of attachment is reduced. Particularly in a display device in which a display area for displaying an image is curved, when the area of attachment is small, because of the restoring force of a substrate curved along the curved surface of a glass cover, the substrate may be removed from the glass cover.

### BRIEF DESCRIPTION OF THE DRAWINGS

FIG. 1 is a plan view showing a general structure of a display device.

FIG. 2 is a cross-sectional view showing a general structure of a display panel in a display area.

FIG. 3 is the cross-sectional view of the display device along line F3-F3 of FIG. 1.

FIG. 4 is a cross-sectional view of the display panel.

FIG. 5 is the cross-sectional view of the display device along line F4-F4 of FIG. 1.

FIG. 6 is a plan view of the display panel before the display panel is attached to a protective member.

FIG. 7 is a cross-sectional view in which an example of an end face of an array substrate is enlarged.

FIG. 8 is a cross-sectional view in which another example of the end face of the array substrate is enlarged.

FIG. 9 is a flowchart showing an example of a method for manufacturing the display device.

FIG. 10 is a cross-sectional view of the display device according to a comparative example shown for comparison with FIG. 5.

FIG. 11 is a cross-sectional view in which an example of an end face of the array substrate is enlarged according to a comparative example shown for comparison with FIG. 7 and FIG. 8.

### DETAILED DESCRIPTION

In general, according to one embodiment, a display device includes an insulating substrate, a supporting substrate, and a protective member. The insulating substrate includes a first upper surface and a first lower surface. The first lower surface is on a side opposite to the first upper surface. The supporting substrate includes a second upper surface and a second lower surface. The second upper surface faces the first lower surface and is attached by a first adhesive layer. The second lower surface is on a side opposite to the second upper surface. The protective member faces the first upper surface and is attached by a second adhesive layer. The second upper surface is smaller than the first upper surface. The first upper surface is smaller than the protective member.

Embodiments will be described hereinafter with reference to the accompanying drawings. Incidentally, the disclosure is merely an example, and proper changes within the spirit of the invention, which area easily conceivable by a skilled person, are included in the scope of the invention as a matter of course. In addition, in some cases, in order to make the description clearer, the widths, thicknesses, shapes and the like of the respective parts are schematically illustrated in the drawings, compared to the actual modes. However, the schematic illustration is merely an example, and adds no restrictions to the interpretation of the invention. Besides, in the specification and drawings, the structural elements having functions which are identical or similar to the functions of the structural elements described in connection with preceding drawings are denoted by like reference numerals, and an overlapping detailed description is omitted unless otherwise necessary.

In each embodiment, as an example of a display device, a display device DSP which is an organic EL display device is disclosed. The display device DSP may be used for various devices such as a smartphone, a tablet terminal, a mobile phone, a personal computer, a television receiver, a vehicle-mounted device, a game console and a wearable terminal.

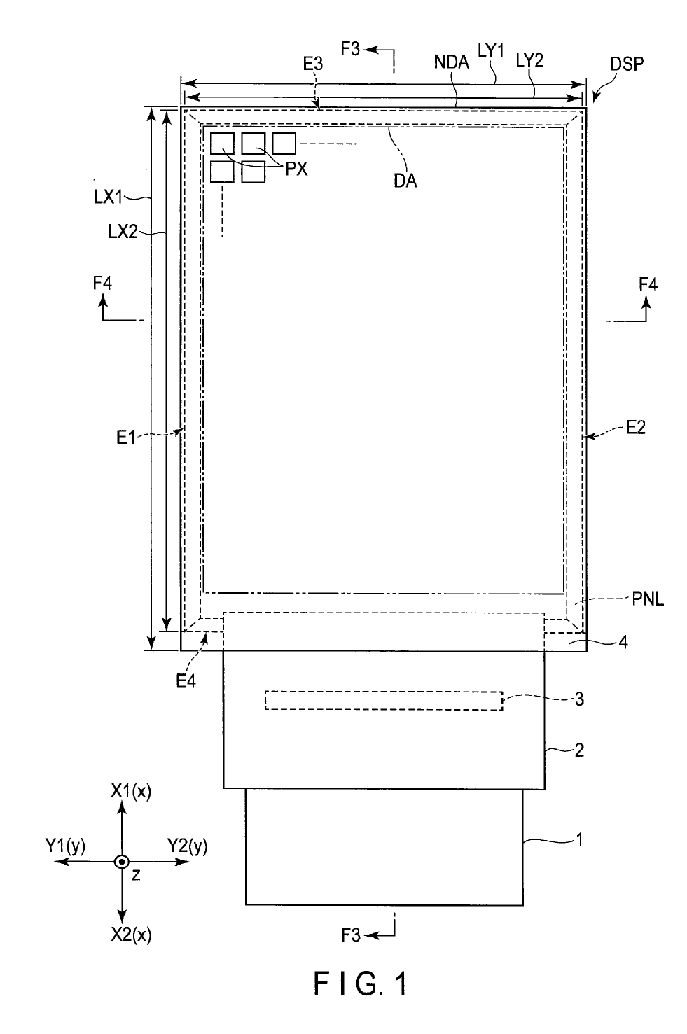

FIG. 1 is a plan view showing a general structure of the display device DSP. FIG. 1 shows an X-Y plane defined by a first direction X and a second direction Y perpendicular to the first direction X. A third direction Z is a direction perpendicular to the first direction X and the second direction Y. In the example of FIG. 1, the first direction X, the second direction Y and the third direction Z are perpendicular to each other. However, they may intersect at an angle other than 90 degrees.

As shown in FIG. 1, the display device DSP comprises a display panel PNL, a first wiring substrate 1, a second wiring substrate 2 and a protective member 4. Although not shown in FIG. 1, the display device DSP may further comprise a touchpanel provided on the display panel PNL, etc.

The display panel PNL comprises a pair of end portions E1 and E2 along the first direction X, and a pair of end portions E3 and E4 along the second direction Y. The display panel PNL comprises a display area DA for displaying an image, and a non-display area NDA surrounding the display area DA.

The display panel PNL comprises a plurality of pixels PX arrayed in matrix in the first direction X and the second direction Y in the display area DA. Each pixel PX is the minimum unit constituting a color image, and includes organic EL elements OLED1, OLED2 and OLED3 as described later.

The first wiring substrate 1 is, for example, a flexible wiring substrate, and is electrically connected to an external signal supply source which supplies a signal to the display panel PNL based on image data.

The second wiring substrate 2 is mounted in the non-display area NDA, and electrically connects the display panel PNL and the first wiring substrate 1. For example, a driver IC chip 3 which drives the display panel PNL is mounted on the second wiring substrate 2. The driver IC chip 3 may be mounted on the display panel PNL or the first wiring substrate 1. The driver IC chip 3 and the signal supply source are examples of drive components which drive the display panel PNL.

The protective member 4 overlaps the display panel PNL in the X-Y plane. In the first direction X, length LX1 of the protective member 4 is greater than length LX2 of the display panel. In the second direction Y, length LY1 of the protective member 4 is substantially equal to length LY2 of the display panel PNL.

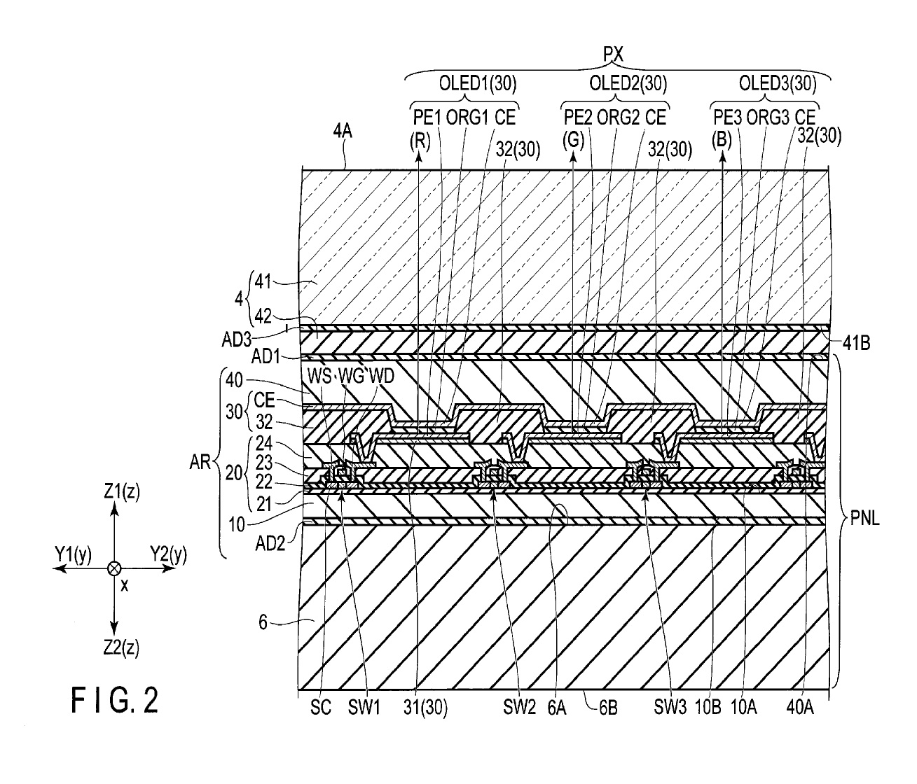

FIG. 2 is a cross-sectional view showing a general structure of the display panel PNL in the display area DA. The protective member 4 faces a supporting substrate 6 in the third direction Z. Hereinafter, the protective member 4 is defined as an upper side Z1 when it is seen from the supporting substrate 6. The supporting substrate 6 is defined as a lower side Z2 when it is seen from the protective member 4.

As shown in FIG. 2, the display panel PNL comprises an insulating substrate 10, switching elements SW1, SW2 and SW3, a reflective layer 31, organic EL elements OLED1, OLED2 and OLED3, a sealing member 40, the supporting substrate 6, etc.

The insulating substrate 10 is formed of, for example, polyimide resin, and comprises a first upper surface 10A, and a first lower surface 10B on a side opposite to the first upper surface 10A. The first upper surface 10A of the insulating substrate 10 is covered with a first insulating film 21.

Switching elements SW1, SW2 and SW3 are formed on the first insulating film 21. In the example of FIG. 2, switching elements SW1, SW2 and SW3 are structured as top-gate thin-film transistors. However, they may be structured as bottom-gate thin-film transistors. Since switching elements SW1, SW2 and SW3 have the same structure, the structure of switching element SW1 is explained in more detail as a representative example. Switching element SW1 comprises a semiconductor layer SC formed on the first insulating film 21. The semiconductor layer SC is covered with a second insulating film 22. The second insulating film 22 is also provided on the first insulating film 21.

Switching element SW1 comprises a gate electrode WG formed on the second insulating film 22 facing the semiconductor layer SC. The gate electrode WG is covered with a third insulating film 23. The third insulating film 23 is also provided on the second insulating film 22. The first to third insulating films 21, 22 and 23 are formed of an inorganic material such as silicon oxide or silicon nitride.

Switching element SW1 comprises a source electrode WS and a drain electrode WD on the third insulating film 23. The source and drain electrodes WS and WD are electrically connected to the semiconductor layer SC through the respective contact holes penetrating the second and third insulating films 22 and 23. Switching element SW1 is covered with a fourth insulating film 24. The fourth insulating film 24 is also provided on the third insulating film 23. The fourth insulating film 24 is formed of an organic material of transparent resin, etc., such as an acrylic organic film or polyimide organic film.

The reflective layer 31 is formed on the fourth insulating film 24. The reflective layer 31 is formed of a metal material having a high optical reflectance such as aluminum or silver. The surface of the reflective layer 31 may be flat, or may be uneven for imparting a light-scattering property.

Organic EL elements OLED1, OLED2 and OLED3 are formed on the fourth insulating film 24, and for example, emit red (R) light, green (G) light and blue (B) light, respectively. Organic EL element OLED1 includes pixel electrode PE1 and organic light-emitting layer ORG1. Similarly, organic EL element OLED2 includes pixel electrode PE2 and organic light-emitting layer ORG2. Organic EL element OLED3 includes pixel electrode PE3 and organic light-emitting layer ORG3. For example, organic light-emitting layer ORG1 is formed of a material which emits light with a red wavelength. Organic light-emitting layer ORG2 is formed of a material which emits light with a green wavelength. Organic light-emitting layer ORG3 is formed of a material which emits light with a blue wavelength. In the example of FIG. 2, organic EL elements OLED1 to OLED3 are defined by ribs 32.

Pixel electrodes PE1, PE2 and PE3 are formed on the reflective layer 31. Organic EL element OLED1 is electrically connected to switching element SW1. Similarly, organic EL element OLED2 is electrically connected to switching element SW2. Organic EL element OLED3 is electrically connected to switching element SW3.

Organic light-emitting layer ORG1 is formed on pixel electrode PE1. Similarly, organic light-emitting layer ORG2 is formed on pixel electrode PE2. Organic light-emitting layer ORG3 is formed on pixel electrode PE3.

Organic EL elements OLED1, OLED2 and OLED3 further include a common electrode CE. The common electrode CE is formed on organic light-emitting layers ORG1 to ORG3. The common electrode CE is also formed on the ribs 32. One of pixel electrode PE1 and the common electrode CE is an anode, and the other one is a cathode. This structure is also applied to pixel electrodes PE2 and PE3. Pixel electrodes PE1, PE2 and PE3 and the common electrode CE are formed of a conductive material having translucency such as indium tin oxide (ITO) or indium zinc oxide (IZO). The reflective layer 31, organic EL elements OLED1, OLED2 and OLED3 and the ribs 32 are collectively called an organic EL structural layer 30.

The sealing member 40 covers organic EL elements OLED1, OLED2 and OLED3. The sealing member 40 prevents the incursion of liquid or gas into organic EL elements OLED1, OLED2 and OLED3 and the degradation of organic EL elements OLED1, OLED2 and OLED3. The sealing member 40 has, for example, a stacked structure comprising an organic film and an inorganic film.

The supporting substrate 6 comprises a second upper surface 6A, and a second lower surface 6B on a side opposite to the second upper surface 6A. The second upper surface 6A of the supporting substrate 6 is attached to the first lower surface 10B of the insulating substrate 10 with adhesive layer AD2. The supporting substrate 6 is formed of resin such as polyethylene terephthalate (PET), and has a strength greater than that of the insulating substrate 10. The supporting substrate 6 prevents the deformation of the display panel PNL and the incursion of liquid or gas into the insulating substrate 10.

The protective member 4 is located on a side facing the first upper surface 10A of the insulating substrate 10, and protects the display panel PNL. The protective member 4 comprises a transparent cover member 41. The cover member 41 is formed of, for example, glass, and may be called a glass cover. The cover member 41 may be formed of resin. In the example of FIG. 2, the protective member 4 comprises a front film 42.

The front film 42 is attached to an upper surface 40A of the sealing member 40 with adhesive layer AD1, and is attached to a lower surface 41B of the cover member 41 with adhesive layer AD3. The front film 42 is, for example, a polarizer which prevents an effect caused by external light. The front film 42 may be a retardation film which compensates the retardation of a circularly-polarized plate, a light transmissive film which protects the sealing member 40, or a stacked film thereof.

As the protective member 4, at least one of the cover member 41 and the front film 42 should function. The protective member 4 is larger than an array substrate AR as seen in plan view.

Each of adhesive layers AD1, AD2 and AD3 is formed of an adhesive. The adhesive includes a pressure-sensitive adhesive. Adhesive layers AD1, AD2 and AD3 may be, for example, double-sided tape in which an adhesive is applied to both sides of a film-like base material.

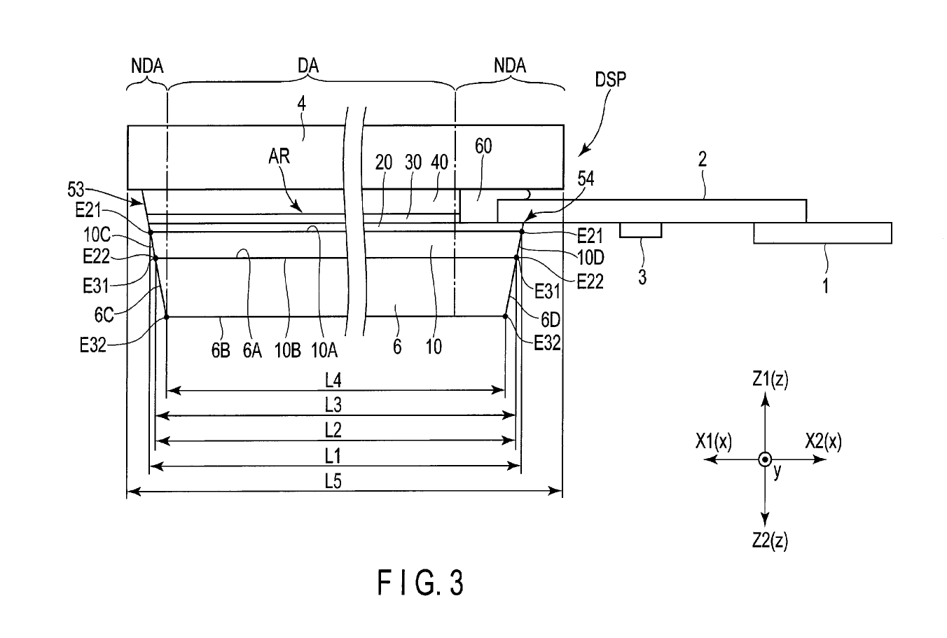

FIG. 3 is the cross-sectional view of the display device DSP along line F3-F3 of FIG. 1. Here, this specification explains the cross-sectional surface of the display device DSP in the X-Z plane defined by the first direction X and the third direction Z.

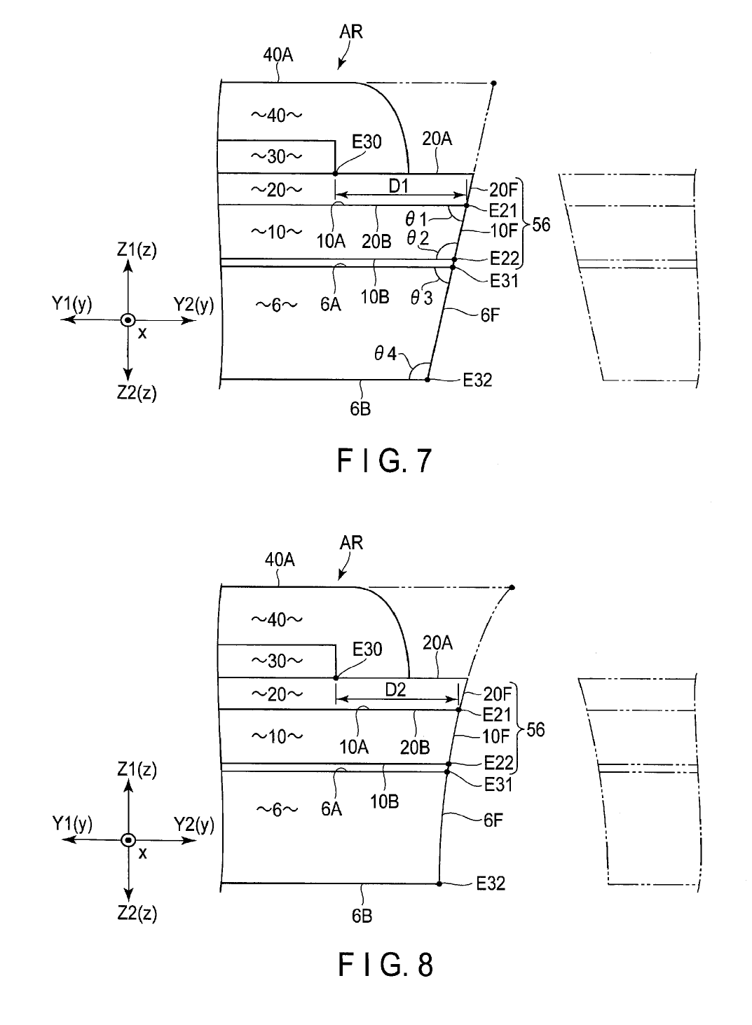

Regarding the insulating substrate 10, the first upper surface 10A is larger than the first lower surface 10B. In the first direction X, length L1 of the first upper surface 10A is greater than length L2 of the first lower surface 10B. The insulating substrate 10 comprises first side surfaces 10C and 10D. Both of first side surfaces 10C and 10D are surfaces inclined with respect to the third direction Z. First side surface 10C is included in end face 53 of the array substrate AR. First side surface 10D is included in end face 54 of the array substrate AR. End face 53 is the surface along end portion E3 of the display panel PNL shown in FIG. 1. End face 54 is the surface along end portion E4 of the display panel PNL. As described later with reference to FIG. 7, the angle between either first side surface 10C or 10D and the second upper surface 10A is an acute angle. The angle between either first side surface 10C or 10D and the first lower surface 10B is an obtuse angle. End portions E21 of the first upper surface 10A are located on the external side, in other words, on a side separating from the display area DA, in comparison with end portions E22 of the first lower surface 10B. First side surfaces 10C and 10D are surfaces linearly connecting end portions E21 of the first upper surface 10A and end portions E22 of the first lower surface 10B.

In the supporting substrate 6, the second upper surface 6A is larger than the second lower surface 6B. In the first direction X, length L3 of the second upper surface 6A is greater than length L4 of the second lower surface 6B. The supporting substrate 6 comprises second side surfaces 6C and 6D. Both of second side surfaces 6C and 6D are surfaces inclined with respect to the third direction Z. As described later, the angle between either second side surface 6C or 6D and the second upper surface 6A is an acute angle. The angle between either second side surface 6C or 6D and the second lower surface 6B is an obtuse angle. End portions E31 of the second upper surface 6A are located on the external side, in other words, on a side separating from the display area DA, in comparison with end portions E32 of the second lower surface 6B. Second side surfaces 6C and 6D are surfaces linearly connecting end portions E31 of the second upper surface 6A and end portions E32 of the second lower surface 6B.

In other words, both the insulating substrate 10 and the supporting substrate 6 comprise a reverse-tapered cross-sectional surface on which the length in the first direction X is increased from the lower side to the upper side in the third direction Z.

Regarding the relationship of the size between the insulating substrate 10 and the supporting substrate 6, the second upper surface 6A is smaller than the first upper surface 10A. Length L3 of the second upper surface 6A is less than length L1 of the first upper surface 10A. Length L2 of the first lower surface 10B is substantially equal to length L3 of the second upper surface 6A. End portions E22 of the first lower surface 10B substantially coincide with end portions E31 of the second upper surface 6A.

Both the insulating substrate 10 and the supporting substrate 6 are smaller than the protective member 4 in the first direction X. Length L5 of the protective member 4 is greater than length L1 of the first upper surface 10A and length L3 of the second upper surface 6A.

The second wiring substrate 2 is mounted between the insulating substrate 10 and the protective member 4, and is attached with resin 60. The second wiring substrate 2 is bent such that the first wiring substrate 1 faces the second lower surface 6B.

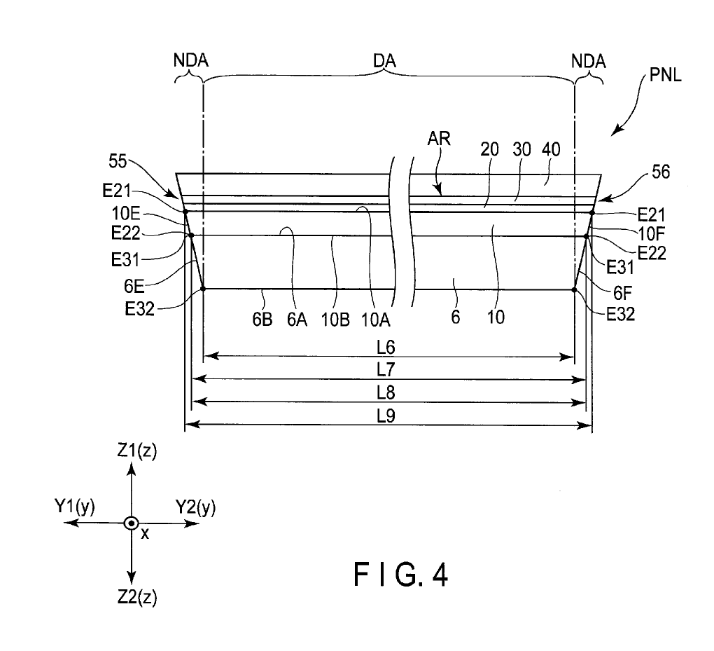

FIG. 4 is the cross-sectional view of the display panel PNL along line F4-F4 of FIG. 1. Here, this specification explains the cross-sectional surface of the display panel PNL in the Y-Z plane defined by the second direction Y and the third direction Z before the display panel PNL is attached to the protective member 4.

Regarding the insulating substrate 10, the first upper surface 10A is larger than the first lower surface 10B. In the second direction Y, length L9 of the first upper surface 10A is greater than length L8 of the first lower surface 10B. The insulating substrate 10 comprises third side surfaces 10E and 10F. Both of third side surfaces 10E and 10F are surfaces inclined with respect to the third direction Z. Third side surface 10E is included in end face 55 of the array substrate AR. Third side surface 10F is included in end face 56 of the array substrate AR. End face 55 is the surface along end portion E1 of the display panel PNL shown in FIG. 1. End face 56 is the surface along end portion E2 of the display panel PNL. As described later, the angle between either third side surface 10E or 10F and the first upper surface 10A is an acute angle. The angle between either third side surface 10E or 10F and the first lower surface 10B is an obtuse angle. End portions E21 of the first upper surface 10A are located on the external side, in other words, on a side separating from the display area DA, in comparison with end portions E22 of the first lower surface 10B. Third side surfaces 10E and 10F are surfaces linearly connecting end portions E21 of the first upper surface 10A and end portions E22 of the first lower surface 10B.

In the supporting substrate 6, the second upper surface 6A is larger than the second lower surface 6B. In the second direction Y, length L7 of the second upper surface 6A is greater than length L6 of the second lower surface 6B. The supporting substrate 6 comprises fourth side surfaces 6E and 6F. Both of fourth side surfaces 6E and 6F are surfaces inclined with respect to the third direction Z. As described later, the angle between either fourth side surface 6E or 6F and the second upper surface 6A is an acute angle. The angle between either fourth side surface 6E or 6F and the second lower surface 6B is an obtuse angle. End portions E31 of the second upper surface 6A are located on the external side, in other words, on a side separating from the display area DA, in comparison with end portions E32 of the second lower surface 6B. In other words, both the insulating substrate 10 and the supporting substrate 6 comprise a reverse-tapered cross-sectional surface on which the length in the second direction Y is increased from the lower side Z2 to the upper side Z1 in the third direction Z. Fourth side surfaces 6E and 6F are surfaces linearly connecting end portions E31 of the second upper surface 6A and end portions E32 of the second lower surface 6B.

Regarding the relationship of the size between the insulating substrate 10 and the supporting substrate 6, length L7 of the second upper surface 6A is less than length L9 of the first upper surface 10A. Length L7 of the first lower surface 10B is substantially equal to length L8 of the second upper surface 6A.

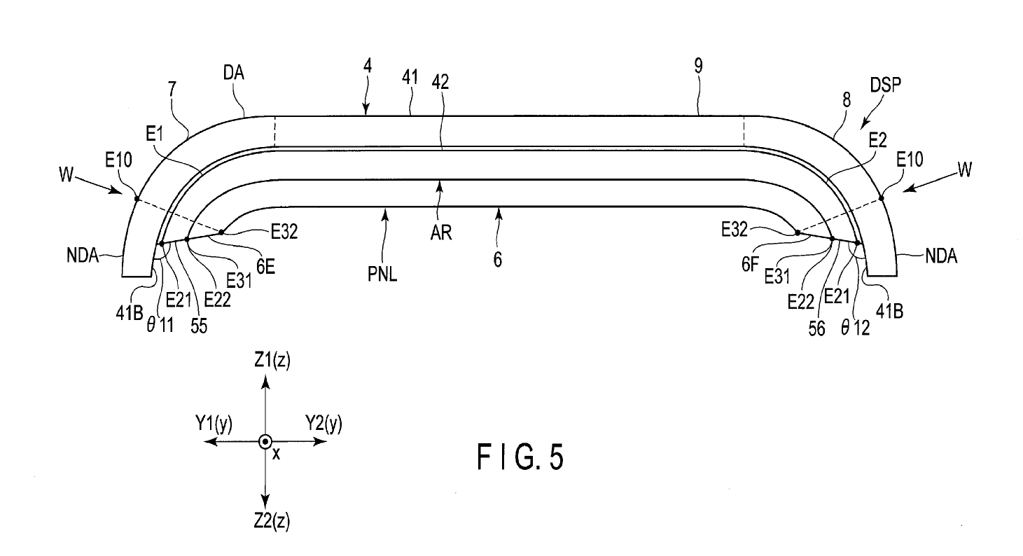

FIG. 5 is the cross-sectional view of the display device DSP along line F4-F4 of FIG. 1. FIG. 5 shows the cross-sectional surface in a state where the display panel PNL shown in FIG. 4 is attached to the protective member 4. As shown in FIG. 5, the protective member 4 comprises a central portion 9, and first and second side portions 7 and 8 on both sides of the central portion 9. The central portion 9 is parallel to the X-Y plane. The first and second side portions 7 and 8 are curved toward the lower side Z2 in comparison with the central portion 9. The display panel PNL is attached along the protective member 4, and is curved toward the lower side Z2 in a manner similar to that of the first and second side portions 7 and 8. The protective base member 4 may have a plate-like shape.

In portions corresponding to the first and second side portions 7 and 8, the display panel PNL includes the organic EL structural layer 30 shown in FIG. 2 and overlaps the display area DA. Both angle θ11 between end face 55 and the lower surface 41B of the cover member 41 and angle θ12 between end face 56 and the lower surface 41B of the cover member 41 are obtuse angles.

As seen in the normal direction W of each of the first and second side portions 7 and 8, end portions E10 of the display area DA substantially coincide with end portions E32 of the second lower surface 6B of the supporting substrate 6. End portions E21, E22 and E31 are located on the lower side Z2 in comparison with the dashed lines connecting end portions E10 and end portions E32 in FIG. 5.

As shown in FIG. 5, both the insulating substrate 10 and the supporting substrate 6 are smaller than the protective member 4 in the second direction Y in a state where the display panel PNL is attached to the protective member 4.

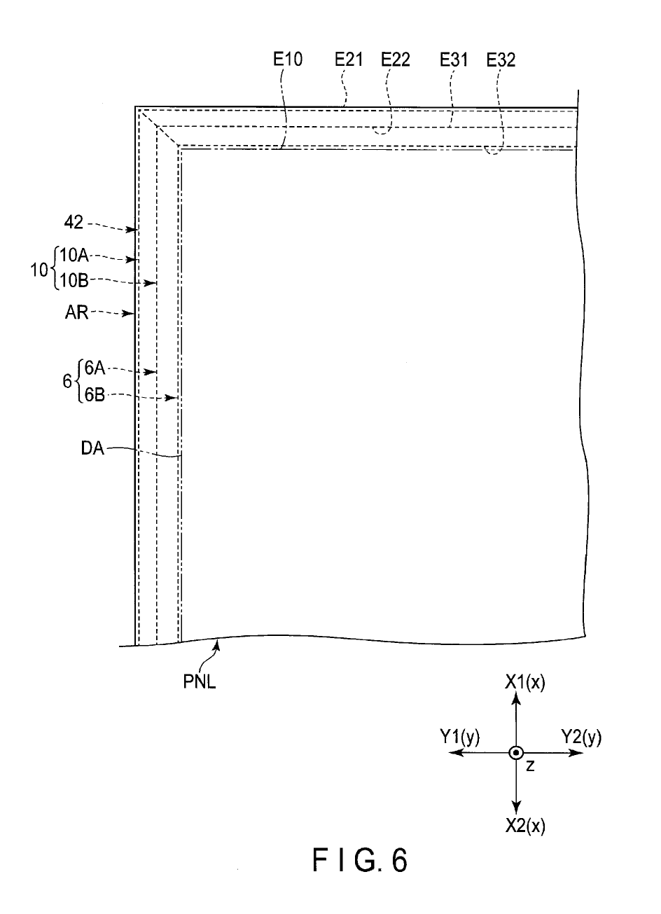

FIG. 6 is a plan view of the display panel PNL before the display panel PNL is attached to the protective member 4. In the example shown in FIG. 6, the front film 42 has a size substantially equal to that of the array substrate AR. The size of the front film 42 is not limited to this example. The front film 42 may be larger than the array substrate AR as a protective member, or may be smaller than the array substrate AR so as to cover only the display area DA.

End portion E10 of the display area DA is located so as to substantially coincide with end portion E32 of the second lower surface 6B. Thus, the second lower surface 6B of the supporting substrate 6 has an area substantially equal to that of the display area DA.

End portion E21 of the first upper surface 10A is located on the external side in comparison with end portion E22 of the first lower surface 10B. Thus, the first upper surface 10A is larger than the first lower surface 10B. End portion E31 of the second upper surface 6A is located on the external side in comparison with end portion E32 of the second lower surface 6B. Thus, the second upper surface 6A is larger than the second lower surface 6B. End portion E22 of the first lower surface 10B is located so as to substantially coincide with end portion E31 of the second upper surface 6A. Thus, the first lower surface 10B has an area substantially equal to that of the second upper surface 6A.

FIG. 7 is a cross-sectional view in which an example of end faces 53, 54, 55 and 56 of the array substrate AR is enlarged. End faces 53 and 55 have substantially the same shape as end face 56. End face 54 has substantially the same shape as end face 56 except for the structure in which the second wiring substrate 2 is mounted. Thus, end face 56 is explained in detail as a representative example, overlapping explanation of end faces 53, 54 and 55 being omitted unless necessary.

As explained with reference to FIG. 4 and FIG. 5, end face 56 of the array substrate AR of the present embodiment includes third side surface 10F of the insulating substrate 10, and a side surface 20F of a barrier film 20. Angle θ1 between third side surface 10F and the first upper surface 10A is an acute angle. Angle θ2 between third side surface 10F and the first lower surface 10B is an obtuse angle. In the example shown in FIG. 7, the side surface 20F of the barrier film 20 makes an acute angle with main surface (upper surface) 20A of the barrier film 20, and makes an obtuse angle with main surface (lower surface) 20B. Main surface 20A exposed from the sealing member 40 is covered with the above adhesive layer AD1 (shown in FIG. 2). In the supporting substrate 6, angle θ3 between fourth side surface 6F and the second upper surface 6A is an acute angle. Angle θ4 between fourth side surface 6F and the second lower surface 6B is an obtuse angle.

An end face of the display panel PNL forms an end face of the display device DSP. End face 56 of the array substrate AR forms an end face of the display panel PNL together with fourth side surface 6F of the supporting substrate 6. Thus, an end face of the display panel PNL of the present embodiment is inclined toward the inner side from the upper side Z1 to the lower side Z2. In the following explanation, this shape is called a reverse-tapered shape.

FIG. 8 is a cross-sectional view in which another example of end faces 53, 54, 55 and 56 of the array substrate AR is enlarged. End face 56 shown in FIG. 8 is different from end face 56 shown in FIG. 7 in respect that end face 56 is curved. In a manner similar to that of the example shown in FIG. 7, in the example shown in FIG. 8, end face 56 makes an acute angle with the first upper surface 10A, and makes an obtuse angle with the first lower surface 10B. In FIG. 7 and FIG. 8, the distance between end portion E21 of the first upper surface 10A of the insulating substrate 10 covered with the barrier film 20 and end portion E30 of the organic EL structural layer 30 is denoted by reference numbers D1 and D2.

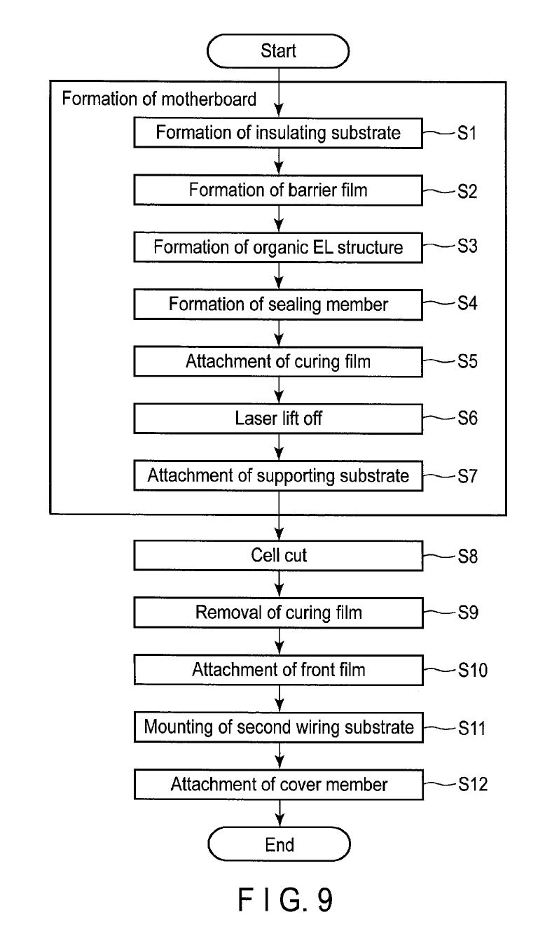

FIG. 9 is a flowchart showing an example of a method for manufacturing the display device DSP. This specification explains a method for manufacturing the display device DSP of the present embodiment with reference to FIG. 9.

In the method for manufacturing the display device DSP, a motherboard comprising a plurality of cells is formed by the motherboard formation of steps S1 to S7. Subsequently, the cells of the motherboard are cut into individual pieces by the cell cut process of step S8. Each cut cell is equivalent to the above array substrate AR. By assembling the display device DSP in the process of steps S9 to S12, the display device DSP shown in FIG. 1 is obtained.

More specifically, in the process for forming an insulating substrate in step S1, for example, the material of the insulating substrate 10 is applied onto a supporting substrate such as a glass substrate, and is cured to form the insulating substrate 10.

In the process for forming a barrier film in step S2, the first to fourth insulating films 21, 22, 23 and 24 are stacked in order on the second upper surface 10A of the insulating substrate 10 to form the barrier film 20. In this process, for example, switching element SW1 shown in FIG. 2 is also formed.

In the process for forming an organic EL structure in step S3, pixel electrode PE1, organic light-emitting layer ORG1 and the common electrode CE are stacked in order on the second main surface 20A of the barrier film 20 to form the organic EL structural layer 30.

In the process for forming a sealing member in step S4, the sealing member 40 covering the organic EL structural layer 30 is formed.

In the process for attaching a curing film in step S5, the upper surface 40A of the sealing member 40 is covered with a curing film. The curing film protects the sealing member 40 and imparts rigidity to prevent the deformation of the insulating substrate 10 in the manufacturing process.

In the laser lift off of step S6, the glass substrate is removed from the insulating substrate 10. When laser light is emitted to the glass substrate from the lower side Z2, the first lower surface 10B of the insulating substrate 10 absorbs laser light and is slightly decomposed. A gap is defined at the interface between the glass substrate and the insulating substrate 10. The glass substrate is removed from the insulating substrate 10.

In the process for attaching a supporting substrate in step S7, the supporting substrate 6 is attached to the first lower surface 10B of the insulating substrate 10.

In the cell cut process of step S8, a motherboard comprising a plurality of array substrates AR is cut into individual array substrates AR.

In the process for removing the curing film in step S9, the curing film is partially removed to form a terminal portion for mounting the second wiring substrate 2 in the non-display area NDA. Subsequently, the remaining curing film is removed.

In the process for attaching a front film in step S10, the front film 42 is attached to the upper surface 40A of the exposed sealing member 40.

In the process for mounting the second wiring substrate in step S11, the second wiring substrate 2 electrically connected to the first wiring substrate 1 is mounted in the terminal portion of an array substrate AR.

In the process for attaching a cover member in step S12, the cover member 41 is attached to an upper surface 5A of the front film 42. In this way, the display device DSP shown in FIG. 1 is manufactured.

To form a reverse-tapered end face of the display panel PNL shown in FIG. 7 and FIG. 8, for example, laser light may be emitted to the motherboard (the array substrates AR before the motherboard is cut into individual pieces) from the lower side Z2 in the cell cut process of step S8. The wavelength of laser light is, for example, 266 or 532 nm.

At the beginning of the cell cut process of step S8, the array substrates AR before cut into individual pieces and the supporting substrate 6 before cut into individual pieces are integrally attached to each other by the process for attaching the supporting substrate in step S7. The laser light emitted from the lower side Z2 simultaneously evaporates the array substrates AR and the supporting substrate 6 integrated with each other. Thus, end face 56 of each array substrate AR and fourth side surface 6F of the supporting substrate 6 are formed in a reverse-tapered shape in substantially the same plane.

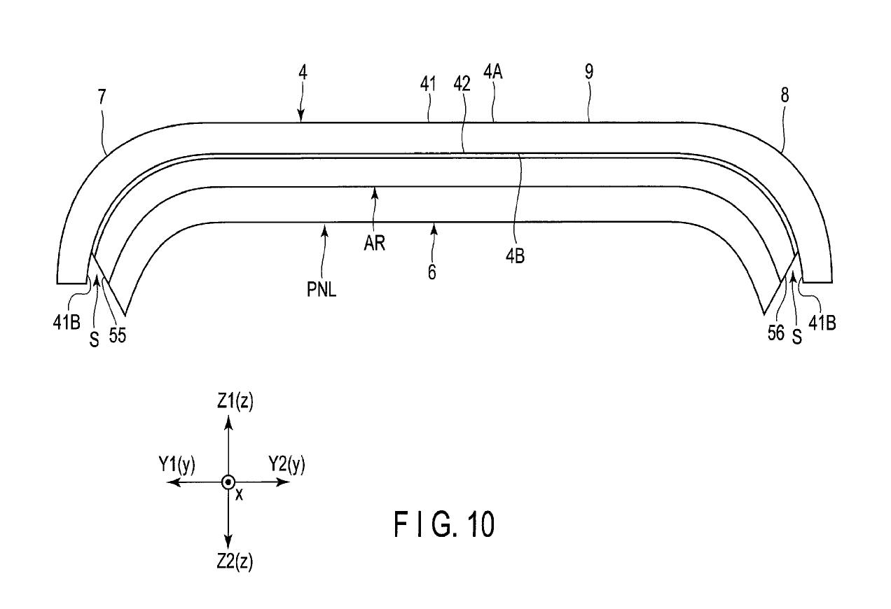

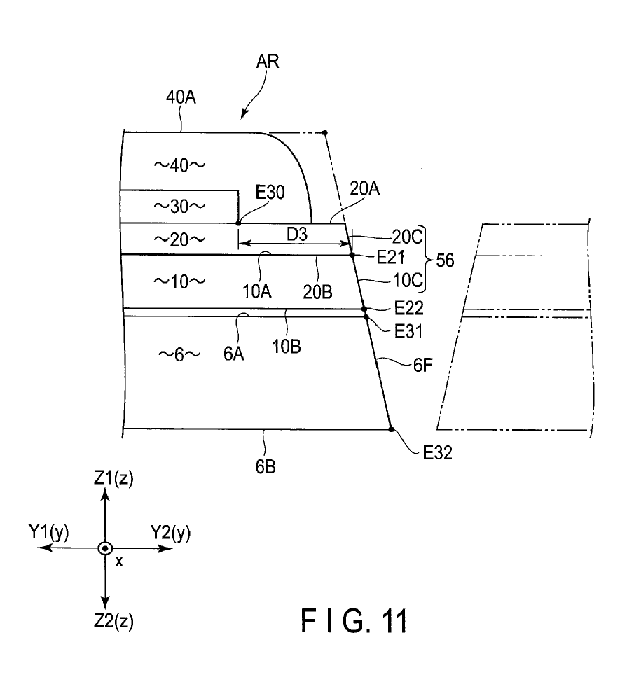

FIG. 10 is a cross-sectional view of the display device DSP according to a comparative example shown for comparison with FIG. 5. In the comparative example shown in FIG. 10, end faces 55 and 56 of the array substrate AR make an acute angle with the lower surface 41B of the cover member 41. In this display device, as shown in FIG. 10, a wedge-shaped gap S is defined between the lower surface 41B of the cover member 41 and end faces 55 and 56 of the array substrate AR.

FIG. 11 is a cross-sectional view in which an example of an end face of the array substrate AR is enlarged according to a comparative example shown for comparison with FIG. 7 and FIG. 8. The distance between end portion E21 of the first upper surface 10A of the insulating substrate 10 covered with the barrier film 20 and the organic EL structural layer 30 is denoted by reference number D3. As shown in FIG. 11, distance D3 of the comparative example is shorter than distances D1 and D2 shown in FIG. 7 and FIG. 8.

In the display device DSP having the above structure in the present embodiment, the supporting substrate 6 is smaller than the insulating substrate 10, and the insulating substrate 10 is smaller than the cover member 41 or the front film 42. Thus, an end face of the display device DSP has a reverse-tapered shape toward the inner side from the upper side Z1 to the lower side Z2 when it is seen in broad perspective. In this manner, it is difficult to define a wedge-shaped gap between the lower surface 41B of the cover member 41 and end faces 53, 54, 55 and 56 of the array substrate AR.

In the present embodiment, end face 56 of the array substrate AR and fourth side surface 6E of the supporting substrate 6 in an end portion of the display device DSP have a reverse-tapered shape in substantially the same plane. Similarly, end face 53 of the array substrate AR and second side surface 6C of the supporting substrate 6 have a reverse-tapered shape in substantially the same plane. End face 54 of the array substrate AR and second side surface 6D of the supporting substrate 6 have a reverse-tapered shape in substantially the same plane. End face 55 of the array substrate AR and fourth side surface 6F of the supporting substrate 6 have a reverse-tapered shape in substantially the same plane. Thus, as shown in the example of FIG. 5, no wedge-shaped gap is defined between the lower surface 41B of the cover member 41 and end face 55 or 56 of the array substrate AR.

If a wedge-shaped gap S is defined between the lower surface 41B of the cover member 41 and end faces 55 and 56 of the array substrate AR as shown in the comparative example of FIG. 10, the array substrate AR is easily removed based on the gap S. In particular, as shown in FIG. 10, in the display device in which the display area DA for displaying an image is curved, because of the restoring force of the array substrate AR curved along the curved surface of the cover member 41, the array substrate AR may be removed from the cover member 41.

In the present embodiment, no gap is defined between a protective film such as the cover member 41 or the front film 42 and the array substrate AR including the insulating substrate 10. Further, the area of attachment between the cover member 41, etc., and the insulating substrate 10 can be increased. Thus, it is possible to prevent the removal from the cover member 41.

In the present embodiment, end faces 50A and 50B of the array substrate AR make an acute angle with the first upper surface 10A of the insulating substrate 10 and make an obtuse angle with the first lower surface 10B. In this structure, the distance between end portion E21 of the first upper surface 10A of the insulating substrate 10 covered with the barrier film 20 and the organic EL structural layer 30 is longer than that of a case where end face 50C makes an obtuse angle with the first upper surface 10A of the insulating substrate 10 and makes an acute angle with the first lower surface 10B.

The barrier film 20 prevents the liquid moving to the organic EL structural layer 30 via the insulating substrate 10 from intruding into the organic EL structural layer 30. In the present embodiment, distances D1 and D2 between end portion E21 of the first upper surface 10A of the insulating substrate 10 covered with the barrier film 20 and the organic EL structural layer 30 can be long. Thus, the reliability for blocking liquid by the barrier film 20 can be improved. As a result, the reliability of the display device DSP can be improved.

Various other desirable effects can be obtained from the present embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, an organic light-emitting layer may be configured to emit white light, and a color filter may be provided in the array substrate or front film at a position corresponding to the organic light-emitting layer. In place of the color filter, a color conversion layer may be provided. For example, although each switching element is structured as a top-gate thin-film transistor in the above embodiment, each switching element may be structured as a bottom-gate thin-film transistor. For example, although each organic EL element is structured as a top-emission type which emits light to the upper side, each organic EL element may be structured as a bottom-emission type which emits light to the lower side.

For example, the display device may be a liquid crystal display device. In this case, an array substrate is equivalent to the insulating substrate 10, and a counter-substrate is equivalent to the front film 42. The array substrate and the counter-substrate may have flexibility. Even when the display device is a liquid crystal display device, in a manner similar to that of the present embodiment, the area of attachment between the cover member and the display device can be increased, thereby preventing the removal from the cover member.

What is claimed is:

1. A display device comprising:
an insulating substrate comprising a first upper surface, and a first lower surface on a side opposite to the first upper surface;
a supporting substrate comprising a second upper surface facing the first lower surface and attached by a first adhesive layer, and a second lower surface on a side opposite to the second upper surface; and
a protective member facing the first upper surface and attached by a second adhesive layer,
the second upper surface being smaller than the first upper surface, and
the first upper surface being smaller than the protective member.

2. The display device of claim 1, wherein
the second lower surface is smaller than the second upper surface.

3. The display device of claim 1, wherein
the insulating substrate comprises a first side surface, and
an angle between the first side surface and the first upper surface is an acute angle.

4. The display device of claim 3, wherein
the protective member comprises a lower surface facing the upper surface, and
an angle between the first side surface and the lower surface is an obtuse angle.

5. The display device of claim 1, wherein
the supporting substrate comprises a second side surface, and
an angle between the second side surface and the second upper surface is an acute angle.

6. The display device of claim 1, wherein
the protective member comprises a first portion, a first side portion and a second side portion,
the first and second side portions are located on both sides of the first portion,
first and second side portions are curved so as to be located on a lower side in comparison with the first portion, and
insulating substrate and the supporting substrate are curved along the protective member.

7. A display device comprising:
a protective member;
an insulating substrate facing the protective member and attached by a second adhesive layer; and
a supporting substrate facing the insulating substrate and attached by a first adhesive layer, wherein
protective member comprises a lower surface facing the insulating substrate,
insulating substrate comprises a first side surface, and
an angle between the lower surface and the first side surface is an obtuse angle.

8. The display device of claim 7, wherein
the protective member comprises a first portion, a first side portion and a second side portion,
the first and second side portions are located on both sides of the first portion, and
the first and second side portions are curved so as to be located on a lower side in comparison with the first portion.

9. The display device of claim 8, wherein
the insulating substrate and the supporting substrate are curved along the protective member.

10. The display device of claim 7, wherein
the insulating substrate comprises a first upper surface attached to the protective member, and a first lower surface on a side opposite to the first upper surface, and
the first lower surface is smaller than the first upper surface.

11. The display device of claim 10, wherein
the supporting substrate comprises a second upper surface attached to the insulating substrate, and a second lower surface on a side opposite to the second upper surface, and
the second lower surface is smaller than the second upper surface.

12. The display device of claim 11, wherein
the first lower surface has a size substantially equal to a size of the second upper surface.
